(19) United States
(12) Patent Application Publication
(10) Pub. No.: US 2026/0246213 A1
(43) Pub. Date: Aug. 20, 2026

(54) HIGH DENSITY CONNECTOR FOR SUPERCONDUCTING APPLICATIONS

(71) Applicant: IQM FINLAND OY, Espoo (FI)

(72) Inventors: Jean-Luc ORGIAZZI, Espoo (FI); Olli-Pentti SAIRA, Espoo (FI)

(21) Appl. No.: 19/137,522

(22) PCT Filed: Dec. 11, 2023
(86) PCT No.: PCT/FI2023/050678

§ 371 Date: Jun. 10, 2025

(30) Foreign Application Priority Data
Dec. 9, 2022 (FI) 20227161

(51) Int. Cl. H01R 24/22; G06N 10/40; H01R 13/6585; H01R 13/719; H01R 43/02; H05K 1/02; H05K 1/03; H05K 3/3494

(52) U.S. Cl. CPC H01R 24/22; G06N 10/40; H01R 13/6585; H01R 13/719; H01R 43/0242; H01R 43/0256; H05K 1/0212; H05K 1/0306; H05K 3/3494

(57) ABSTRACT

The invention relates to a connector for electrically connecting a plurality of transmission lines to another component. The connector comprises a ceramic body and a plurality of contacts located on a surface of the ceramic body. Each contact is connected to one of the plurality of transmission lines, and the connector is configured to be electrically connected to the other component by connecting the contacts of the connector to contacts on the other component. The invention also includes a high density attenuator or filter bank, which may be connected to the connector, and a method for forming a connection using the connector.

### TECHNICAL FIELD

The invention in generally related to material science. In particular, the invention is related to ceramic based materials suitable for various solutions in cryogenic environments and superconducting applications, such as quantum information processing and quantum hardware.

### BACKGROUND

The heart of a superconducting QPU is a silicon or sapphire chip, with qubit structures made of superconducting metal on top of it. In a large QPU, the qubits will be arranged in a two-dimensional lattice. To route control signals into the middle of the lattice, wires need to be brought in from a direction perpendicular to the plane.

The wiring solution needs to simultaneously meet several criteria, which include: high bandwidth (for some signals), controlled impedance, low cross-talk, low dissipation, low microwave loss, shielding of qubit circuits from lossy materials, tight pitch compatible with the dimensions of the QPU unit cell and number of signals per unit cell, high reliability, and the ability to replace the QPU.

Ceramic technology as a packaging solution for semiconductor dies in general is well known, for example in solutions using a silicon substrate and multi-layer wiring using planarized dielectric material.

### SUMMARY

This summary is provided to introduce a selection of concepts in a simplified form that are further described below in the detailed description. This summary is not intended to identify key features or essential features of the claimed subject matter, nor is it intended to be used to limit the scope of the claimed subject matter. It is an objective to provide a novel material comprising ceramic and a metal component that provides superconducting properties into the functional ceramic substrate. The material can be manufactured with known manufacturing methods, e.g. by utilizing low temperature co-fired ceramics (LTCC) base or green sheets or other substrates to which a mixture of suitable metal and e.g. a polymer carrier is deposited as a layer and then prefired or dried; functionalized layers developed as needed on top of the prefired green sheets, including for example physical two-dimensional or three-dimensional structures such as trough-vias, cavities, routes etc and finally pressed and fired so as to achieve a functionalized multilayer structures that can be utilized as components for several different purposes as disclosed in the following.

This kind of material has many beneficial properties including high stiffness, conductivity properties, thermal expansion coefficient suitable for various applications, impermeability to gases (because of the glass-like composition after firing) and machineability, to mention a few. It can also be readily used as a base layer or interposer layer for various purposes.

The solution meets all the engineering criteria disclosed in the Background section, while being relatively cheap and scalable to large substrate sizes (up to 6″ or 15.24 cm) and a large number of wiring layers (up to 38 layers) using readily available processes. It should be noted that the compressible springs require a significant amount of force (typ. 10 grams per contact) and the ceramic layer is needed to avoid extensive bowing of the chip stack, which would compromise the usability of the QPUs and the superconducting chips.

The problem(s) the invention solves include:
vertical delivery of signals and fan-out of signals from dense pitch silicon TSV pads array to traditional PCBs
proposing a material with CTE closer to silicon than traditional PCBs
higher signal to signal isolation than SiO2/Si multilayer wiring
stiffness of rigid ceramic stack might allow the use of compressible spring contacts for reusable packages and easy sample swap->enabling high throughput good-sample discovery.

The proposed technical solutions and possible alternatives include a ceramic based multilayer (30~50 layers possible) interposer with Indium-based solder contacts or spring contacts.

A first aspect of the invention relates to a connector for electrically connecting a plurality of transmission lines to another component. The connector comprises a ceramic body and a plurality of contacts located on a surface of the ceramic body. Each contact is connected to one of the plurality of transmission lines, and the connector is configured to be electrically connected to the other component by connecting the contacts of the connector to contacts on the other component.

Connecting the contacts of the connector to contacts on the other component may comprise soldering the contacts of the connector to contacts on the other component.

The connector may further comprise one or more heating elements configured to generate sufficient heat to reflow solder located on the contacts. The one or more heating elements may be integrated into the ceramic body.

The connector may comprise a thermal sensor for measuring heat generated by the heating elements.

The connector may further comprise alignment features for aligning the connector with the other component. The alignment features constrain relative moment of the connector and the other component in at least three perpendicular directions.

The pitch of the plurality of contacts on the surface of the ceramic body may be is less than 1 mm.

The transmission lines may be coaxial cables and the centre conductor of each coaxial cable may be connected to one of the plurality of contacts.

Each coaxial cable may terminate within the ceramic body of the connector such that the centre conductor of the coaxial cable is connected to the contact within the ceramic body, and wherein the contact comprises a metallic trace that extends from the interior of the ceramic body to the exterior of the ceramic body in at least in a longitudinal direction defined by the axis of the coaxial cable.

The contact may also extend in a perpendicular direction, which is perpendicular to the longitudinal direction, such that the position of the contact on the exterior of the ceramic body is not aligned with the centre conductor of the coaxial cable.

The shield of each coaxial cable may also be connected to one or more metallic traces that extend from the interior of the ceramic body to the exterior of the ceramic body, each metallic trace forming or being connected to one or more shield contacts on the exterior of the ceramic body, the one or more shield contacts being adjacent to but not in contact with the contact connected to the centre conductor of the coaxial cable.

The one or more shield contacts may include at least two shield contacts, and the shield contacts may be arranged regularly around the contact connected to the centre conductor and equidistant from the contact connected to the centre conductor.

A second aspect of the invention relates to a cable comprising a plurality of transmission lines, a first connector as described above located at a first end of the plurality of transmission lines, and a second connector at a second end of the plurality of transmission lines.

A third aspect of the invention relates to a high density attenuator or filter bank comprising a ceramic body, a first plurality of contacts located on a surface of the ceramic body, a second plurality of contacts located on a surface of the ceramic body, and a plurality of filters and/or attenuators connected to the first plurality of contacts and second plurality of contacts such that each contact in the first plurality of contacts is connected to a contact of the second plurality of contacts via one or more of the filters and/or attenuators.

The high density attenuator or filter bank may be connected to the described above such that each contact of either the first plurality of contacts or second plurality of contacts of the high density attenuator or filter bank is connected to one of the of contacts located on the surface of the ceramic body of the connector.

A fourth aspect of the invention relates to a method for connecting a plurality of transmission lines to another component using a connector that comprises a ceramic body and a plurality of contacts located on a surface of the ceramic body, wherein each contact is connected to one of the plurality of transmission lines, and wherein a connecting element is present on each contact of the connector and/or corresponding contacts on the other component. The method comprises aligning the contacts of the connector with the contacts of the other component and connecting the contacts of the connector to the contacts of the other component using the connecting elements.

The connecting elements may be solder bumps. The connector may comprise one or more heating elements and connecting the contacts of the connector to the contacts of the other component may comprise using the one or more heating elements to generate sufficient heat to reflow the solder.

The connector may further comprise one or more thermal sensors for measuring heat generated by the one or more heating elements and the heat generated by the one or more heating elements may be controlled based on measurements obtained using the one or more thermal sensors.

Prior to soldering the contacts, the method further comprises removing oxide from the solder bumps.

Prior to soldering the contacts, the method may further comprise placing a jacket enclosure around the contacts and filling the space enclosed by the jacket enclosure with reducing gas and/or inert gas to minimise or prevent oxidation of the solder when soldering the contacts.

Aligning the contacts of the connector with the contacts of the other component may be carried out using alignment features present on the connector and the other component.

A clamping mechanism may be used to secure the connector and the other object during soldering.

The connecting elements may be indium bumps and connecting the contacts of the connector to the contacts of the other component may comprise compression bonding using the indium bumps.

The other component may be a second connector comprising a ceramic body and a plurality of contacts located on a surface of the ceramic body, wherein each contact is connected to one of a second plurality of transmission lines.

### BRIEF DESCRIPTION OF THE DRAWINGS

FIG. 1 depicts a conventional manufacturing method for ceramic functional layer.

FIG. 2 depicts a schematic QPU or chip stack with an interposer layer made of the superconducting material.

FIG. 3 depicts a connector according to the present invention.

FIG. 4A is a cross section of the connector of FIG. 3.

FIG. 4B shows the arrangement of connectors on the bottom of the connector of FIG. 4A.

FIG. 5 depicts a connector and high density ceramin filter/attenuator bank.

FIG. 6 depicts a “pig tail” connection of two connectors.

### DETAILED DESCRIPTION

The invention comprises a general idea of utilizing a ceramic material as a component in a chip such as a superconducting chip comprising at least one QPU, similar to a conventional semiconductor chip on a printed circuit board. Since the ceramic material can be made superconducting as described above, it is particularly suitable for superconductors, for example in quantum computers with quantum processing units, QPUs.

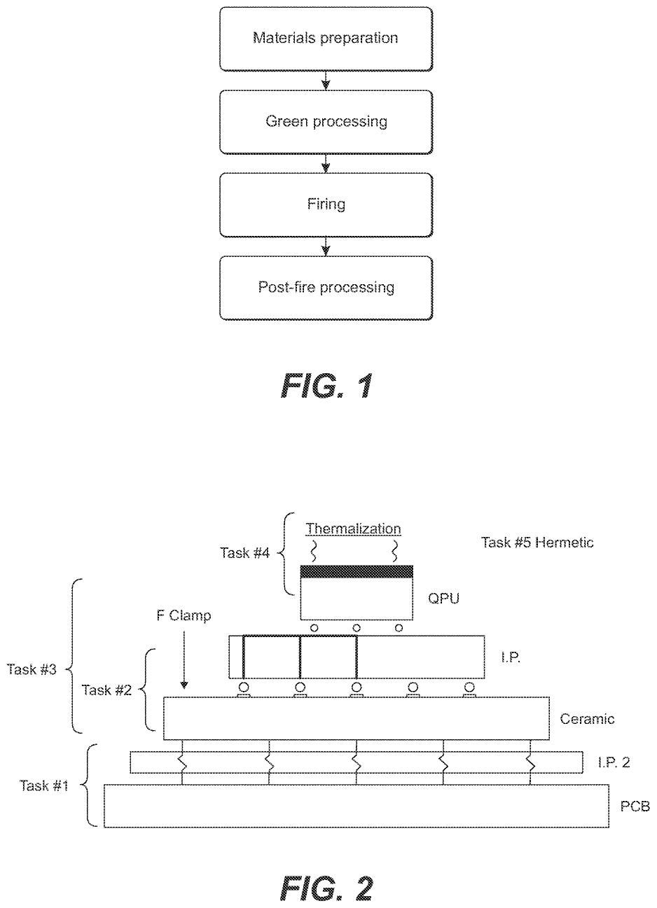

In essence the ceramic material can be made superconducting by including a suitable superconducting (metal) material into its composition, for example by introducing a superconducting material into a slurry coating a LTCC green base material or sheet and manufacturing ceramic multilayer structures from that via conventional manufacturing methods as known in the field (see FIG. 1), e.g. introducing the metal material onto a green sheet in a slurry with a suitable binding component, such as polymer and firing the resulting composition to provide a single body of superconducting ceramic material. This superconducting material could, for example, be aluminium-based, or comprise niobium, molybdenum or tungsten. Especially the last two may be suitable due to their high melting point. A ceramic material of such a composition or even with a suitable metal layer provides a low-loss routing structure within a chip layer made of this material, such as an interposer layer in a stack of chips. The superconducting ceramic material is amorphous and has virtually no resonance. As an alternative to LTCCs, high-temperature co-fired ceramics (HTCCs) may be used, along with tungsten, molybdenum, niobium (e.g. niobium nitride), and/or titanium (e.g. titanium nitride) based metal pastes or slurries.

The resulting superconducting ceramic material can be freely modified e.g. by machining it into desired shapes or structures having cavities, routing channels (either vertical or lateral), inlays or any other suitable structures in, on or through the material layer. Niobium-based superconducting ceramic material is used for various superconducting applications. It is for example fully compatible for any currently known flip-chip construction, and many more can be envisioned. Aluminium nitrate is also a possible superconducting component that could be used. A printed circuit board made of the superconducting ceramic material according to the invention could be used as a base layer for a superconducting chip stack comprising a large number of qubits on the QPU layer as relatively large PCBs could be manufactured because of the stiffness of the ceramic material. It could be possible to manufacture QPU stacks comprising >1000 qubits this way.

The ceramic material according to the invention can be used as interposer layer(s) in a superconducting QPU stack (see FIG. 2), to provide structural integrity to a stack comprising a QPU and a dielectric insulation layer on top of a printed circuit board (PCB). The control lines delivering signals and needed electrical components can be embedded or brought through the ceramic interposer layer(s) bonded to the QPU chip layer by for example indium bumps, as is known from flip-chip type of QPUs according to state of art. A number of electronic lines can be brought through the ceramic interposer layer according to the invention by using so-called through-vias similarly to common silicon chip layers where trough-silicon-vias are utilized for this purpose, without compromising the structural integrity of the ceramic interposer layer. Thereafter, the stack of different layers can be pressed together to form a stacked superconductor element or chip by pressing on the ceramic interposer layer instead of the fragile QPU or flip-chip layer. On the PCT, ardent connectors or equivalent can be used to direct the control lines outside the chip stack. It is thus possible to align and press the stack together to connect with the ardent connector pins without breaking the structurally fragile parts or layers of the stack. The ceramic interposer layer can also be used to deliver signals via lines embedded in the lateral direction of the interposer layer. In essence the ceramic interposer layer may thus be a functional structure rather than a mechanical structure.

Alternatively or additionally, the chip stack is a wiring stack that has spring contact pins (‘pogo pins’ or ‘fuzz buttons’) at one interface in the stack, and indium or low-temperature solder contacts at another interface in the stack, and the ceramic layer is used to route electrical signals between the two interfaces.

A stack of interposers as shown in FIG. 2. The components from top to bottom are. 1) QPU chip (“QPU” in sketch). 2) First Interposer (“I.P.”) that is a Silicon chip with thru-silicon via's, with superconducting patterned metallization on both faces. 3) A ceramic wiring layer (“Ceramic”). 4) A second interposer (“I.P2”) 5) A traditional printed circuit board (“PCB”). The electrical contacts at the QPU-I.P. and the Ceramic-I.P. interface are realized as indium or low-temperature solder balls or bumps. The electrical contacts between the Ceramic and the PCB layers are realized as compressible springs embedded in IP2. The ceramic layer is pressed down (with force Fclamp) by a torus-shaped clamp that is not shown.

Many variants are possible. The PCB layer could be replaced with a block into which coaxial wires terminate (similar to an Ardent TR intreface). The compressible springs could be regular solder joints.

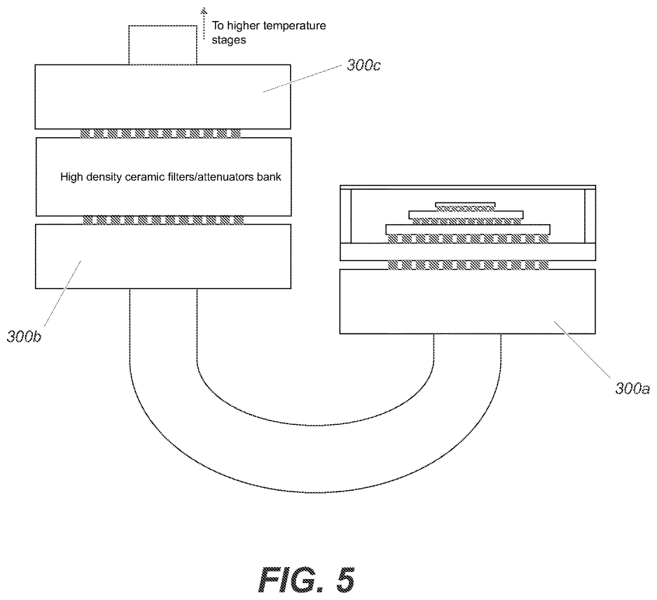

The superconducting ceramic material may be utilized in vacuum environmentally-controlled packaging of QPUs. For example, a suitable gas can be introduced into the cavity around a QPU to prevent oxidation and degradation of the QPU structure over time. In FIG. 5, such a construction is presented in an exemplary manner. It includes a ceramic packaging structure or stack with a base layer machined to create a suitable cavity for the QPU together with a top layer, and channels coated in metal to create suitable outputs for control lines to control the environment inside the QPU cavity. The controlling may include elements such a s an absorber (such as one of activated charcoal, zeolite or palladium or palladium composite), and a molecular sieve for absorbing harmful substances smaller than a particular molecule size. In addition, the control lines can be used to homogenize the temperature within the package.

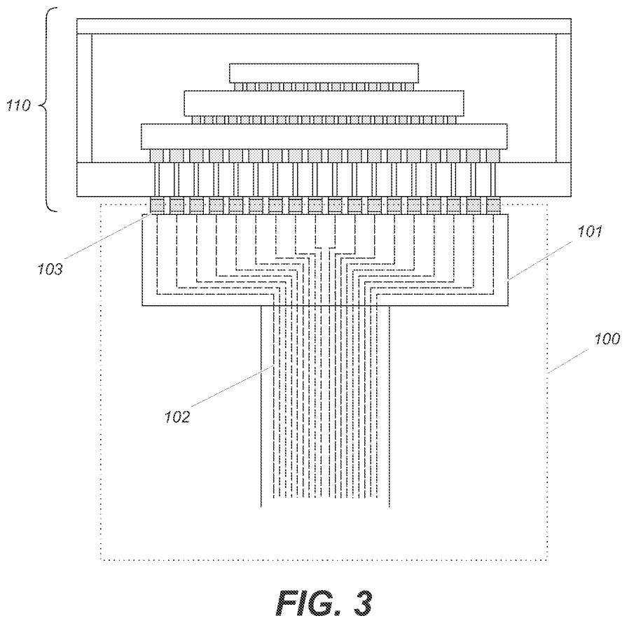

The superconducting ceramic material may also be utilized in ceramic-based high-density transmission line (e.g. microwave) connector applications, for example for directing signals from room-temperature environment to a cryostat or between the different temperature zones of a cryostat. FIG. 3 depicts a ceramic-based high-density connector 100, for electrically connecting a plurality of transmission lines 102 to another component 110. The other component may be a quantum processing unit (QPU) as depicted in FIG. 3, or any other component to which it may be desirable to connect a plurality of transmission lines. The connector 100 may also be used to connect to another, similar connector in pigtail-type configuration. In this context, the term “connector” means a component for connecting the plurality of transmission lines to another component, including both removable/reversible connections and permanent connecting. Similarly, the term “connecting” means either fixed or temporary connection, including but not limited to soldering, contact pins, fuzz buttons, and compressed indium bumps.

The connector 100 has a ceramic body 101, which may be made of the superconducting ceramic material described above. The superconducting ceramic material enables reducing the dimensions of the connector significantly. For example, in a connector dimensionally equivalent to an multiposition high frequency connector, e.g. an Ardent connector, hundreds of lines could be implemented instead of the 24 of an Ardent connector.

The transmission lines 102 may be implemented by nanoscale or picoscale coaxial cables, available to be purchased commercially. Such cables could be arranged into a grid, e.g. a 50×50 or 100×100 lateral construction.

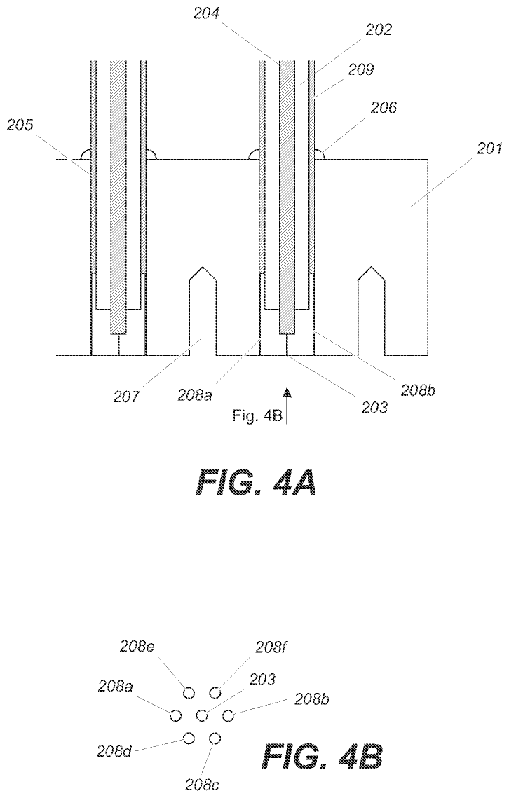

The connector is connected to the other component via contacts 103, which may be, e.g. contact pads, contact pins, or any other element suitable for providing an interface for an electrical connection between the transmission lines of the connector and the corresponding contacts on the other component 110. A specific embodiment of the connectors 103 is depicted in FIGS. 4A and 4B.

Where transmission lines 102 are provided by coaxial cables, the centre conductor of each coaxial cable may be connected to a single corresponding contact on the other component, and further contacts may be provided for connecting the shield of each cable to a corresponding contact on the other component e.g. for connection the shield to ground or to the shield of another coaxial cable. The connector of the present invention may be used with other types of cable, for example twin axial cables.

In FIG. 4A, a cross-section of an exemplary connector is presented. The connector body 201 is a machined ceramic material, such as the superconducting ceramic material described above, with a suitable size and shape and size to allow use with different multiwire connector solutions. Transmission lines 202 are positioned within machine openings in the connector body 201. In the example depicted in FIG. 4, the transmission lines 202 are coaxial cables, e.g. pico-coax cables with an outer diameter in the range of 0.25-0.4 μm. The coaxial cable 202 include an inner core, i.e. the centre conductor, 204 which extends through the body 201 to the opposite surface of the body 201 to the surface in which the coaxial cable enters, and an outer shield 209. Each coaxial cable terminates within the ceramic body 201 of the connector, where the centre conductor 204 is connected to a metallic trace which extends from the centre conductor to the exterior of the ceramic body 201, where it forms or is connected to a contact 203. The metallic trace extends at least partially in a longitudinal direction aligned (and optionally coaxial) with the centre conductor of the coaxial cable 204. The metallic trace may extend from the centre conductor 204 to the exterior of the ceramic body 201 in a linear fashion, as shown in FIG. 4A, or it may follow an indirect path from the centre conductor 204 to the exterior of the ceramic body, i.e. with one or more sections that extend in a direction perpendicular to the axis of the centre conductor 204. In this way, the arrangement (e.g. the pitch) of the contacts 203 on the exterior surface 201 of the ceramic body may be different from the arrangement of the coaxial cable entering the ceramic body. This may be particularly advantageous for reducing the pitch of the contacts 203 compared to the pitch of the coaxial cable 202, which may have a larger lower-limit due to the physical size of each coaxial cable 202.

The shield 209 of each coaxial cable may also be connected to metal traces 208a, 208b, which extend from shield, which also terminates within the interior of the ceramic body 201, to the exterior of the ceramic body 201, where they form or are connected to shield contacts. Like the metal traces/contacts 203 connected to the centre conductor 204, the metal traces 208a, 208b extend at least partially in a longitudinal direction aligned with the centre conductor of the coaxial cable 204. The metallic traces may extend from the shield 209 to the exterior of the ceramic body 201 in a linear fashion, as shown in FIG. 4A, or they may follow indirect paths from the shield 209 to the exterior of the ceramic body, i.e. with one or more sections that extend in a direction perpendicular to the axis of the centre conductor 204. Each of the metallic traces 208a, 208b may follow parallel or symmetric paths or the paths may be different. In this way, the shield contacts on the exterior of the ceramic body 201 may be closer to the contact 203 connected to the centre conductor 204, allowing a tighter pitch of contacts than the pitch of coaxial cables entering the ceramic body 201.

FIG. 4B shows an example of the arrangement of contacts on the exterior surface of the ceramic body 201. Contact 203 connected to the centre conductor 204 of the coaxial cable 202 is surrounded by contacts 208a-f, which are connected to the shield 209 of the coaxial cable 202. The contacts 208a-f are preferably all equidistant to the contact 203, and arrange regularly around the contact 203.

Alternatively to the example depicted in FIGS. 4A and 4B, the contacts corresponding to the contact 103 described above with respect to FIG. 3 are merely the exposed ends 203 of the centre conductors 204, but other contacts may be used. A stop may be present at the end of the opening in the body 201. The stop may have an opening large enough for the centre conductor of the coaxial cable to pass through, but not the rest of the body of the cable. The holes in the body 201 through which the coaxial cables pass may have metallized sidewalls 205 for preventing cross-talk or other interference in the transmission lines 202.

The transmission lines 202 may be held in place in the body 201 by adhesive 206 or other fixing means, e.g. solder or epoxy.

The body 201 may also include alignment features 207 for aligning the connector with the other component to which the connector is to be connected. For example, the connector shown in FIG. 4 includes alignment holes 207 for receiving alignment pins extending from the other component. In general, alignment features at least partially constrain relative movement of the connector and other component to which the connector is connected. Preferably, relatively movement is constrained in three perpendicular directions, i.e. towards and/or away from the other component and in two perpendicular directions perpendicular to the towards/away axis. The alignment features may allow auto-planarization of the contacts on the connector and the other component and therefore a uniform separation between the connector and the other component. In other words, the relative tilt of the connector and other component may also be controlled by the alignment features.

The above-described connector could be used as a cryogenic alternator between the different temperature zones of a cryostat, enabling efficient delivery of signals through electrical lines realized through the superconducting ceramic material-based connectors. For example, cables formed using the connector described above may be used to provide signal lines to and from the different temperature zones of a cryostat all the way to the QPU, and alternatively or additionally, to and from the cryostat to the room temperature environment. This would significantly reduce the space taken up by wiring and cabling, and also reduce the thermal load from the signal lines. Such an arrangement is illustrated in FIG. 5, where a first connector 300a is connected to a QPU and a second connector 300b, connected to the first connector 300a at the other end of a cable, is connected to a further component, e.g. a high-density ceramic filter/attenuator bank. This further component may be located e.g. in a mixing chamber of a cryostat and may be at the interface between different temperature zones of the cryostat. On the opposite side of this component, e.g. in a different temperature zone of the cryostat, a third connector 300c is connected and used to carry transmission lines further to higher temperature stages of the cryostat.

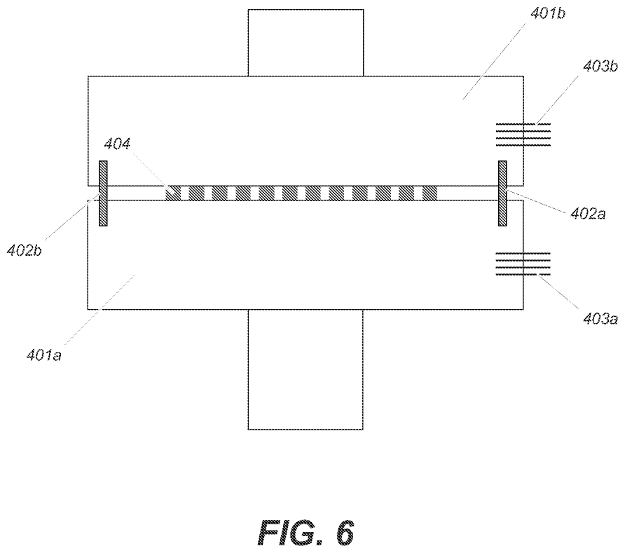

FIG. 6 shows an exemplary arrangement in which two connectors are connected in a “pigtail” type arrangement, i.e. the connectors join two sections or wiring together, rather than connecting wiring to a fixed component. Each connector has a body 401a, 401b that includes alignments features 402a, 402b, as discussed above with respect to FIG. 4. The connectors are joined together by solder balls 404, e.g. indium balls. In the example depicted in FIG. 6, each connector also includes a heating element 403a, 403b for generate sufficient heat to reflow solder located on the contacts of the connectors. The use of the heating elements enables a durable, high-quality connection between connectors while also being formable and breakable without extensive external equipment or processes. The heating elements (303a, 303b) may be integrated into the ceramic body 401a, 401b of each connector in order to provide evenly-distributed heat across the contacts. The connector may also include one or more thermal sensor for measuring heat generated by the heating elements 403a, 403b. The output of the sensor(s) may be used to control the heat generated by the heating elements 403a, 403b to ensure sufficient but not excessive heat is generated.

The invention also relates to a method for connecting a plurality of transmission lines to another component using the connector described above. At a first step, the contacts of the connector are aligned with the contacts of the other component. Aligning the contacts of the connector with the contacts of the other component may be carried out using alignment features present on one of or both the connector and the other component, as described above. In the context of a superconducting quantum computer, a quantum processing unit is installed within a cryostat capable of producing and maintaining the cryogenic temperatures required for the superconducting effects that are exploited in a superconducting quantum computer to arise. It is therefore typical for many of the installation steps to be performed within the cryostat, e.g. connecting signal lines between different temperature zones of the cryostat and ultimately connecting those signal lines to the QPU. The connector and method of the present invention simplifies this method of installing and commissioning a superconducting quantum computer. In particular, construction of the connector per se can be performed in a different environment, i.e. outside of the cryostat, where a wider range of fabrication techniques may be used, such as wet or dry processes that may damage the cryostat, e.g. atmospheric plasma system surface preparation or plasma cleaning with reducing gases (e.g. hydrogen, carbon monoxide) for oxide removal. Only the final steps of connecting the connector to one or more other components may need to be performed within the cryostat, in which case an inert chamber/local glove-box may be provided around the cryostat.

After aligning, the contacts of the connector are connected to the contacts of the other component using the connecting elements. As discussed above, “connecting” may be performed by any suitable method for forming an electrical connection between the transmission lines of the connector and the contacts of the other component, including but not limited to soldering, compression bonding, fuzz buttons, and pogo pins.

The connector and/or the other component includes a number of connected elements present on each contact of the connector and/or the corresponding contacts on the other component.

When the connecting elements are solder bumps and the connector includes one or more heating elements as described above, connecting the contacts of the connector to the contacts of the other component is carried out using the one or more heating elements to generate sufficient heat to reflow the solder. The thermal sensors described above for measuring heat generated by the one or more heating elements may be used to control the heat generated by the one or more heating elements.

Before soldering the contacts, the method further include a set of removing oxide from the solder bumps. The step may include placing a jacket enclosure around the contacts and filling the space enclosed by the jacket enclosure with reducing gas and/or inert gas to minimise or prevent oxidation of the solder when soldering the contacts.

A clamping mechanism may be used to secure the connector and the other object during soldering. The clamping mechanism may be part of the alignment features, e.g. jack screws, or a separate component. The clamping mechanism may also be used when other types of connection are used, e.g. to provide compression for compression bonding using indium bump, or to hold fuzz button/pogo pins in contact.

1. A connector for electrically connecting a plurality of transmission lines to another component, the connector comprising a ceramic body, and a plurality of contacts located on a surface of the ceramic body, wherein each contact is connected to one of the plurality of transmission lines, and wherein the connector is configured to be electrically connected to the other component by connecting the contacts of the connector to contacts on the other component.

2. The connector of claim 1, wherein the connecting the contacts of the connector to contacts on the other component comprises soldering the contacts of the connector to contacts on the other component.

3. The connector of claim 2, wherein the connector further comprises one or more heating elements configured to generate sufficient heat to reflow solder located on the contacts.

4. The connector of claim 3, wherein the one or more heating elements are integrated into the ceramic body.

5. The connector of claim 4, wherein the connector further comprises a thermal sensor for measuring heat generated by the heating elements.

6. The connector of claim 1, wherein the connector further comprises alignment features for aligning the connector with the other component, wherein the alignment feature constrains relative moment of the connector and the other component in at least three perpendicular directions.

7. The connector of claim 1, wherein a pitch of the plurality of contacts on the surface of the ceramic body is less than 1 mm.

8. The connector of claim 1, wherein the transmission lines are coaxial cables and wherein a centre conductor of each coaxial cable is connected to one of the plurality of contacts.

9. The connector of claim 8, wherein each coaxial cable terminates within the ceramic body of the connector such that the centre conductor of the coaxial cable is connected to the contact within the ceramic body, and wherein the contact comprises a metallic trace that extends from the interior of the ceramic body to the exterior of the ceramic body in at least in a longitudinal direction defined by the axis of the coaxial cable.

10. The connector of claim 9, wherein the contact also extends in a perpendicular direction, which is perpendicular to the longitudinal direction, such that the position of the contact on the exterior of the ceramic body is not aligned with the centre conductor of the coaxial cable.

11. The connector of claim 10, wherein a shield of each coaxial cable is connected to one or more metallic traces that extend from the interior of the ceramic body to the exterior of the ceramic body, each metallic trace forming or being connected to one or more shield contacts on the exterior of the ceramic body, the one or more shield contacts being adjacent to but not in contact with the contact connected to the centre conductor of the coaxial cable.

12. The connector of claim 11, wherein the one or more shield contacts comprises at least two shield contacts, and wherein the shield contacts are arranged regularly around the contact connected to the centre conductor and equidistant from the contact connected to the centre conductor.

13. A cable comprising a plurality of transmission lines, a first connector according to claim 1 at a first end of the plurality of transmission lines and a second connector according to any preceding claim at a second end of the plurality of transmission lines.

14. A high density attenuator comprising a ceramic body, a first plurality of contacts located on a surface of the ceramic body, a second plurality of contacts located on a surface of the ceramic body, and a plurality of filters and/or attenuators connected to the first plurality of contacts and second plurality of contacts such that each contact in the first plurality of contacts is connected to a contact of the second plurality of contacts via one or more of the filters and/or attenuators.

15. The high density attenuator of claim 14, wherein the high density attenuator is connected to a connector comprising a ceramic body, and a plurality of contacts located on a surface of the ceramic body, wherein each contact is connected to one of a plurality of transmission lines, and wherein the connector is configured to be electrically connected to another component by connecting the contacts of the connector to contacts on the another component connector; wherein the high density attenuator is connected such that each contact of either the first plurality of contacts or second plurality of contacts of the high density attenuator or filter bank is connected to one of the of contacts located on the surface of the ceramic body of the connector.

16. A method for connecting a plurality of transmission lines to another component using a connector that comprises a ceramic body and a plurality of contacts located on a surface of the ceramic body, wherein each contact is connected to one of the plurality of transmission lines, and wherein a connecting element is present on each contact of the connector and/or corresponding contacts on the other component, the method comprising:
aligning the contacts of the connector with the contacts of the other component; and
connecting the contacts of the connector to the contacts of the other component using the connecting elements.

17. The method of claim 16, wherein the connecting elements are solder bumps, and the connector comprises one or more heating elements, and wherein connecting the contacts of the connector to the contacts of the other component comprises using the one or more heating elements to generate sufficient heat to reflow the solder.

18. The method of claim 17, wherein the connector further comprises one or more thermal sensors for measuring heat generated by the one or more heating elements, and wherein the heat generated by the one or more heating elements is controlled based on measurements obtained using the one or more thermal sensors.

19. The method of claim 18, wherein prior to soldering the contacts, the method further comprises removing oxide from the solder bumps.

20. The method of claim 19, wherein prior to soldering the contacts, the method further comprises placing a jacket enclosure around the contacts and filling a space enclosed by the jacket enclosure with reducing gas and/or inert gas to minimize or prevent oxidation of the solder when soldering the contacts;
wherein aligning the contacts of the connector with the contacts of the other component is carried out using alignment features present on the connector and the other component;
wherein a clamping mechanism is used to secure the connector and the other component during soldering;
wherein the connecting elements are indium bumps and wherein connecting the contacts of the connector to the contacts of the other component comprises compression bonding using the indium bumps; and
wherein the other component is a second connector comprising a ceramic body and a plurality of contacts located on a surface of the ceramic body, wherein each contact is connected to one of a second plurality of transmission lines.

21. (canceled)

22. (canceled)

23. (canceled)

24. (canceled)
